(19) United States
(12) Patent Application Publication
(10) Pub. No.: US 2015/0060292 A1
(43) Pub. Date: Mar. 5, 2015

(54) Method for Forming Three Dimensional Circuit

(71) Applicant: WEI-LIN LIU, Hukou Township (TW)

(72) Inventor: WEI-LIN LIU, Hukou Township (TW)

(21) Appl. No.: 14/016,015

(22) Filed: Aug. 30, 2013

(51) Int. Cl. H05K 3/02; C23C 14/34; C25D 7/12; B23K 26/36

(52) U.S. Cl. CPC H05K 3/027; B23K 26/365; C23C 14/34; C25D 7/12
USPC 205/164; 204/192.1

(57) ABSTRACT

A method for a forming three dimensional circuit is provided. A plastic base is provided. A metal layer is bonded on the plastic base by a metal coating process. The thickness of the metal layer is thickened by an electroplating process. The metal layer is trimmed to form a circuit pattern thereon by a laser engraving process, whereby, the working-hours can be reduced and the cost of material can also be reduced when the three dimensional circuit is manufactured.

### FIELD OF THE INVENTION

The present invention relates to a method for forming a three dimensional circuit, and in particular to the three dimensional circuit is formed by a laser engraving process.

### BACKGROUND OF THE INVENTION

The microlithography process in the traditional semiconductor industry lithography and the associated micro-fabrication technology is based on photolithography etching process. The photolithography imaging resolution and is proportional to the wavelength of the light source, so the resolution has its limits, and these processes are very complex and expensive.

In recently, the circuit type of microelectronic circuit which is circuit gradually progress from two dimensional circuit to three dimensional circuit. For the non-flat surface transfer circuit technology is necessary, but for traditional photolithography process, even a slight surface will because the depth of focus is insufficient for transferring the pattern on the non-flat surface even the surface is a slight curve surface.

The current three dimensional circuit manufacturing process utilizes the laser engraving to trim a special material substrate with metal component to form a desired circuit pattern. Therefore, the metal plating process is performed in the circuit pattern region which can be called as Laser Direct Structure (LDS) Technology. This technology is flexibility in circuit design, simple steps, but also saves the space and greatly favored. However, the base material price is expensive, and the desired circuit pattern region for the laser engraving has long working hours.

### SUMMARY OF THE INVENTION

According to above drawbacks of the three dimensional circuit manufacturing process, the present invention provides a three dimensional circuit forming method. The steps include that a plastic based is provided. A metal layer is bonded on a surface of the plastic base by a metal coating process. The thickness of the metal layer is thickened by an electroplating process. The metal layer is trimmed by a laser engraving process to form a circuit pattern.

Because of the design process for the three dimensional circuit is simple, the required tooling tailor is based on the existing plant equipment, which can be easily imported directly into the production lines, such that the manufacturing cost can be saved. In addition, the laser engraving process can use for the circuit with smaller wire path, and thus the shape of the circuit can be more complex so as to the application range can be enhanced to meet the manufacture of the electronics production trends to slim and light.

### BRIEF DESCRIPTION OF THE DRAWINGS

The present invention will be apparent to those skilled in the art by reading the following description of a preferred embodiment thereof with reference to the drawings, in which:

FIG. 1 is a process flow of the three dimensional circuit forming method in accordance with the present invention;

FIG. 2 is a perspective view of the metal layer on the plastic base to form a coating film on the plastic base in accordance with the three dimensional circuit forming method of the present invention;

FIG. 3 is a perspective view of the thickness of the metal layer is thickened in accordance with the present invention; and

FIG. 4 is a perspective view of the circuit pattern is constituted to form a three dimensional circuit three dimensional circuit in accordance with an embodiment of the present invention.

### DETAILED DESCRIPTION OF THE PREFERRED EMBODIMENT

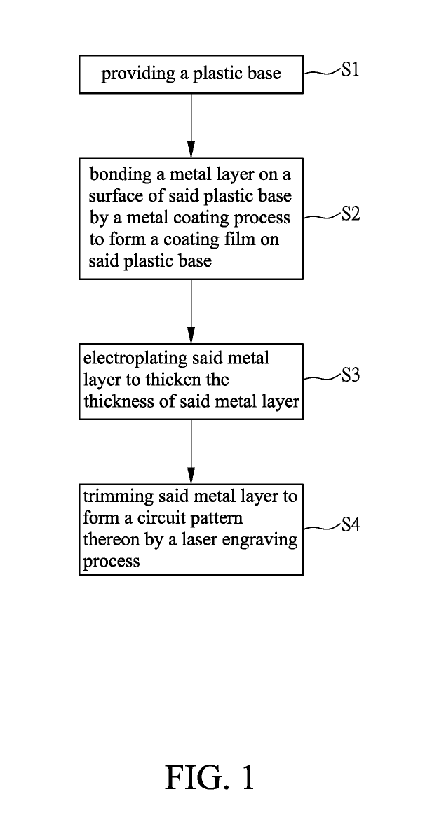

Please refer to FIG. 1. FIG. 1 shows a process flow of the three dimensional circuit forming method of the present invention. The steps of the process flow includes a plastic base is provided as denoted as step S1. A metal layer is bonded on a surface of the plastic base to form a coating film on the plastic base as denoted as step S2. The thickness of the metal layer is thickened by an electroplating process as denoted as step S3. The metal layer is trimmed by a laser engraving process to form a circuit pattern as denoted as step S4.

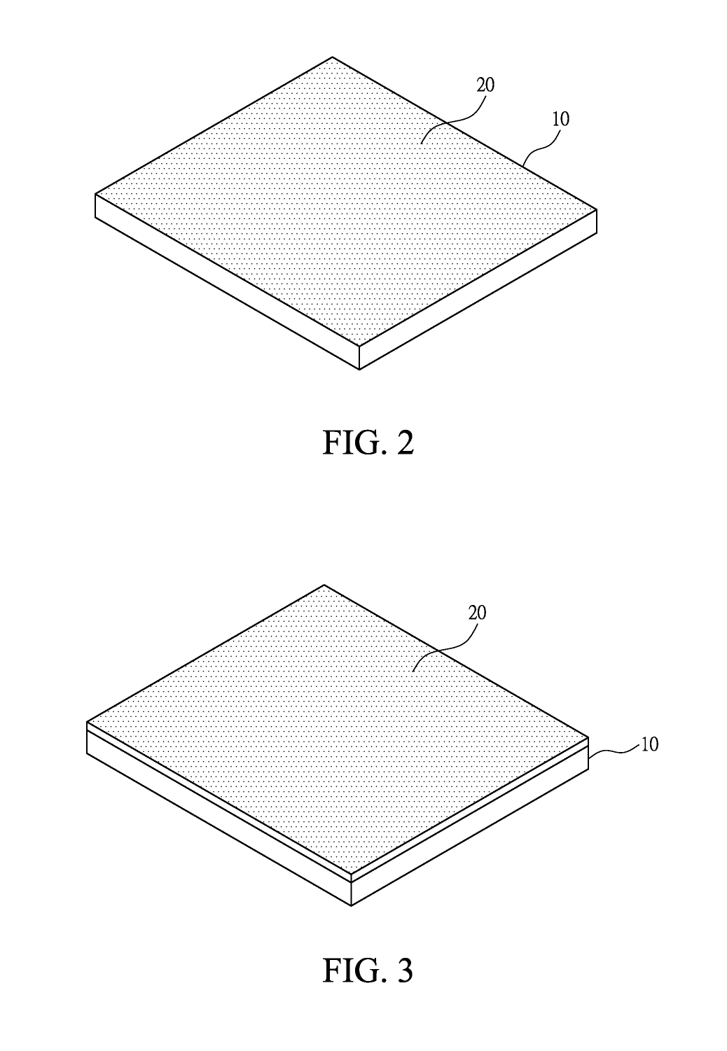

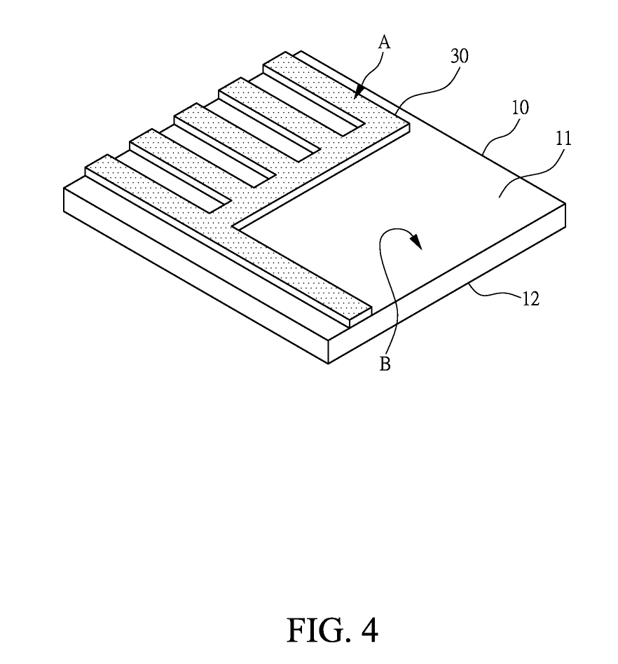

Please refer to FIG. 2 through FIG. 4. The material of the plastic base 10 such as a print circuit board or a plastic case which is formed by injection molding, in which the surface of the plastic base 10 can be a flat surface or non-flat surface. The plastic base 10 includes a first surface 11 and a second surface 12 opposite to the first surface 11. The metal layer 20 is bonded on one surface of the first surface 11 and the second surface 12 to form a coating film 20 on the plastic base 10. The metal coating process such as sputtering, electroplating, and chemical plating, but it is not limited herein. In addition, the metal layer is a metal foil. The thickness of the metal layer is thickened by an electroplating process, in which the electroplating process such as sputtering, electroplating, or chemical plating. The thickness of the thickened metal layer is range about 5 um and 8 um, and the thickened metal layer can be copper, nickel, gold, or alloy. In addition, the region is designed for the desired circuit pattern that is formed on the metal layer, and the region is defined as an “A” region. Other than the “A” region is defined as a “B” region. Then, the metal layer of the “B” region is removed by a laser engraving process, and the metal layer of the “A” region is remained such that the metal layer of the “A” region can be a three dimensional circuit pattern.

The advantage of the three dimensional circuit of the present invention is that the plastic base 10 can be general plastic chassis so as to the acquisition cost of the material can be reduced. The manufacturing process can be simplified due to the metal layer 20 is bonded on the surface of the plastic base 10 by metal coating process to thicken the thickness of the metal layer, such that the effective of the production can be enhanced. In addition, the coating film is trimmed to a circuit pattern 30 by laser engraving with the advantage of the circuit rapid prototyping.

According to the abovementioned, the three dimensional circuit of the present invention can reduce costs and improve efficiency effectively. Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method for forming a three dimensional circuit, comprising:
providing a plastic base;
bonding a metal layer on a surface of said plastic base by a metal coating process to form a coating film on said plastic base;
electroplating said metal layer to thicken the thickness of said metal layer; and
trimming said metal layer to form a circuit pattern thereon by a laser engraving process.

2. The method according to claim 1, wherein a surface of said plastic base is a flat surface.

3. The method according to claim 1, wherein a surface of said plastic base is non-flat surface.

4. The method according to claim 1, wherein said plastic substrate includes a first surface and a second surface opposite to said first surface, and said metal layer is bonded on one of said first surface and said second surface of said plastic base.

5. The method according to claim 1, wherein said electroplating is selected from the group consisting of sputtering and chemical plating.

6. The method according to claim 1, wherein an outside circuit pattern on said metal layer is removed by said laser engraving process.
